(19) United States
(12) Patent Application Publication
(10) Pub. No.: US 2006/0035487 A1
(43) Pub. Date: Feb. 16, 2006

(54) Flexible hybrid cable

(75) Inventor: Arif Maskatia, Milpitas, CA (US)

Correspondence Address: BANNER & WITCOFF, 1001 G STREET N W, SUITE 1100, WASHINGTON, DC, 20001, US

(73) Assignee: ACER INC., Hsichih (TW)

(21) Appl. No.: 10/916,468

(22) Filed: Aug. 12, 2004

(51) Int. Cl. H05K 1/00

(52) U.S. Cl. 439/67

(57) ABSTRACT

A flexible hybrid cable for transmitting signals between first and second devices includes a pair of hybrid connectors, each of which has a FPC terminal set and a wire terminal unit, a flexible printed circuit cable line connected electrically to the FPC terminal sets of the hybrid connectors for establishing a first signal transmission path between the first and second devices; and a wire cable line connected electrically to the wire terminal units of the hybrid connectors for establishing a second signal transmission path that is useful for high speed signal transmission between the first and second devices.

### BACKGROUND OF THE INVENTION

1. Field of the Invention

This invention relates to a flexible hybrid cable, more particularly to a flexible hybrid cable including a pair of hybrid connectors connected electrically to a flexible printed circuit cable line and a wire cable line.

2. Description of the Related Art

Flexible printed circuit (FPC) cables have the advantages of weight and space savings, a reduction in manual connections, elimination of wiring errors, and a high circuit density. However, in some applications, such as to interconnect an expansion base unit (which can include a USB 2.0 port, a keyboard, a hard disk, an optical disk drive, a PS2 port, a battery unit, speakers, etc.) to a Slate computer which is rotatable and slidable relative to the expansion base unit, when the length of the FPC cable is too long, attenuation loss of some high speed signals, such as USB 2.0 running under 400 MHz, can exceed the maximum allowable attenuation loss requirement.

### SUMMARY OF THE INVENTION

The object of the present invention is to provide a flexible hybrid cable that is capable of overcoming the aforesaid drawback associated with the prior art.

According to one aspect of this invention, there is provided a flexible hybrid cable for transmitting signals between first and second devices. The flexible hybrid cable comprises: a pair of hybrid connectors, each of which has a FPC terminal set and a wire terminal unit; a flexible printed circuit cable line connected electrically to the FPC terminal sets of the hybrid connectors for establishing a first signal transmission path between the first and second devices; and a wire cable line connected electrically to the wire terminal units of the hybrid connectors for establishing a second signal transmission path that is useful for high speed signal transmission between the first and second devices.

According to another aspect of this invention, there is provided a flexible cable for transmitting signals between first and second devices. The flexible cable comprises: a flexible printed circuit cable line; and a pair of hybrid connectors, each of which has a first connector housing, a second connector housing connected directly to the first connector housing, a FPC terminal set mounted in the first connector housing and connected electrically to the flexible printed circuit cable line so as to establish a first signal transmission path between the first and second devices, and a wire terminal unit that includes a FPC-end-terminal set mounted in the first connector housing, and a wire-end-terminal set connected electrically to the FPC-end-terminal set, mounted in the second connector housing, and adapted to be connected to a wire cable for establishing a second signal transmission path that is useful for high speed signal transmission between the first and second devices.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a schematic diagram of the preferred embodiment of a flexible hybrid cable according to this invention;

FIG. 2 is a schematic top view of the preferred embodiment of the flexible hybrid cable according to this invention;

FIG. 3 is a schematic side view of the preferred embodiment;

FIG. 4 is a schematic bottom view of the preferred embodiment;

FIG. 5 is a schematic view to illustrate how the flexible hybrid cable interconnects a slate computer and an expansion base unit;

FIG. 6 is a schematic view to illustrate the details of one of two hybrid connectors of the flexible hybrid cable of the preferred embodiment to be connected electrically to the expansion base unit; and

FIG. 7 is a schematic view to illustrate the details of a coaxial cable to be connected to the hybrid connectors of the flexible hybrid cable of the preferred embodiment; and

FIG. 8 is an attenuation loss graph for a FPC cable, an coaxial cable, and a Twinax cable.

### DETAILED DESCRIPTION OF THE PREFERRED EMBODIMENT

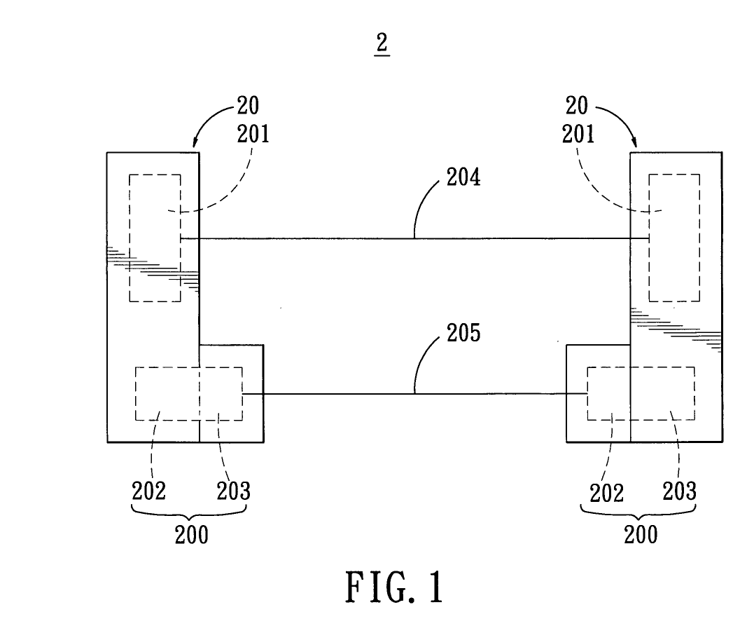

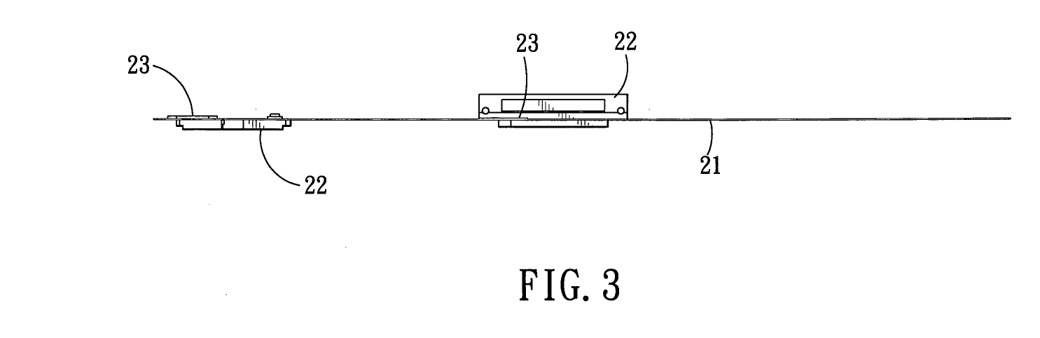

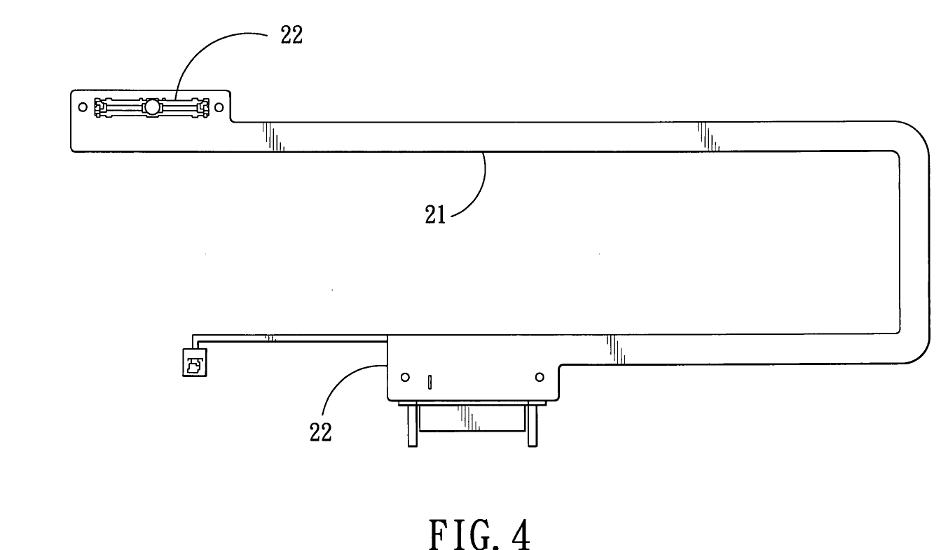

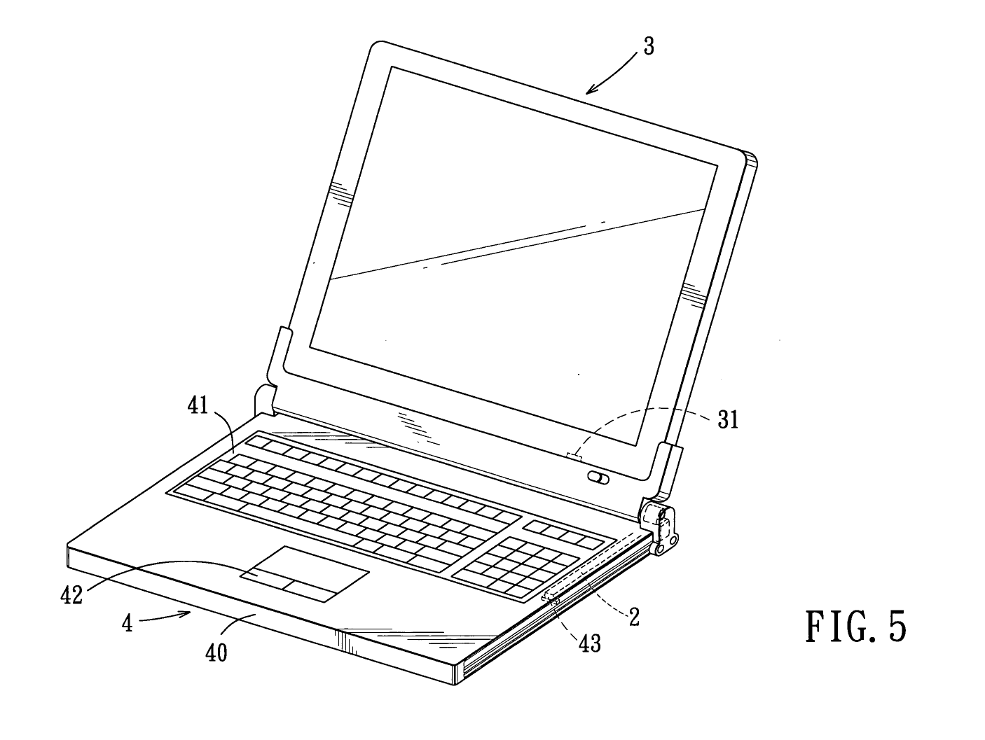

FIGS. 1 to 5 illustrate the preferred embodiment of a flexible hybrid cable 2 according to the present invention for transmitting signals between first and second devices 3, 4 (see FIG. 5). As an example, the flexible hybrid cable 2 of this invention can be applied to notebook computers, such as the one disclosed in co-pending U.S. patent application Ser. No. 10/456,537 filed by the applicant on Jun. 9, 2003. In this application, the first device 3 is a slate computer, while the second device 4 is an expansion base unit 4 that includes a housing 40, a keyboard 41, a touch pad 42, a hard disk drive (not shown), etc. The flexible hybrid cable 2 is connected electrically to a base connector 43 in the housing 40 of the second device 4, extends therefrom along one side of the housing 40, and is connected electrically to the first device 3 through a slate connector 31. The first device 3 is rotatable and slidable frontwardly and rearwardly relative to the second device 4.

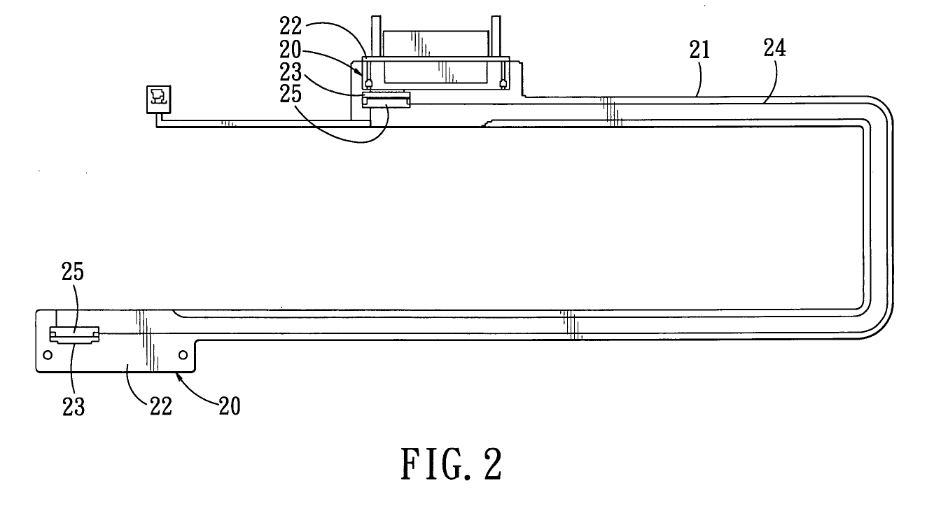

The flexible hybrid cable 2 includes: a pair of hybrid connectors 20, each of which has a FPC terminal set 201 and a wire terminal unit 200; a flexible printed circuit (FPC) cable line 21 (see FIG. 2) connected electrically to the FPC terminal sets 201 of the hybrid connectors 2 for establishing a first signal transmission path 204 (see FIG. 1) between the first and second devices 3, 4; and a wire cable line 24 connected electrically to the wire terminal units 200 of the hybrid connectors 2 for establishing a second signal transmission path 205 that is useful for high speed signal transmission, such as a USB 2.0 signals, LAN signals, Audio signals, and VGA signals, between the first and second devices 3, 4.

In this embodiment, the wire terminal unit 200 includes a FPC-end-terminal set 202 (see FIG. 1) and a wire-end-terminal set 203 connected electrically to the FPC-end-terminal set 202. Each of the hybrid connectors 20 includes a first connector housing 22 for housing the FPC terminal set 201 and the FPC-end-terminal set 202 of the wire terminal unit 200, and a second connector housing 23 for housing the wire-end-terminal set 203 of the wire terminal unit 200. The second connector housing 23 is connected directly and securely to the first connector housing 22.

Preferably, the wire cable line 24 is a coaxial cable line, is attached to the FPC cable line 21, and extends along the length of the FPC cable line 21. A pair of cable connectors 25 (see FIG. 2) are connected electrically to the wire cable line 24, and mate respectively with the second connector housings 23 of the hybrid connectors 20.

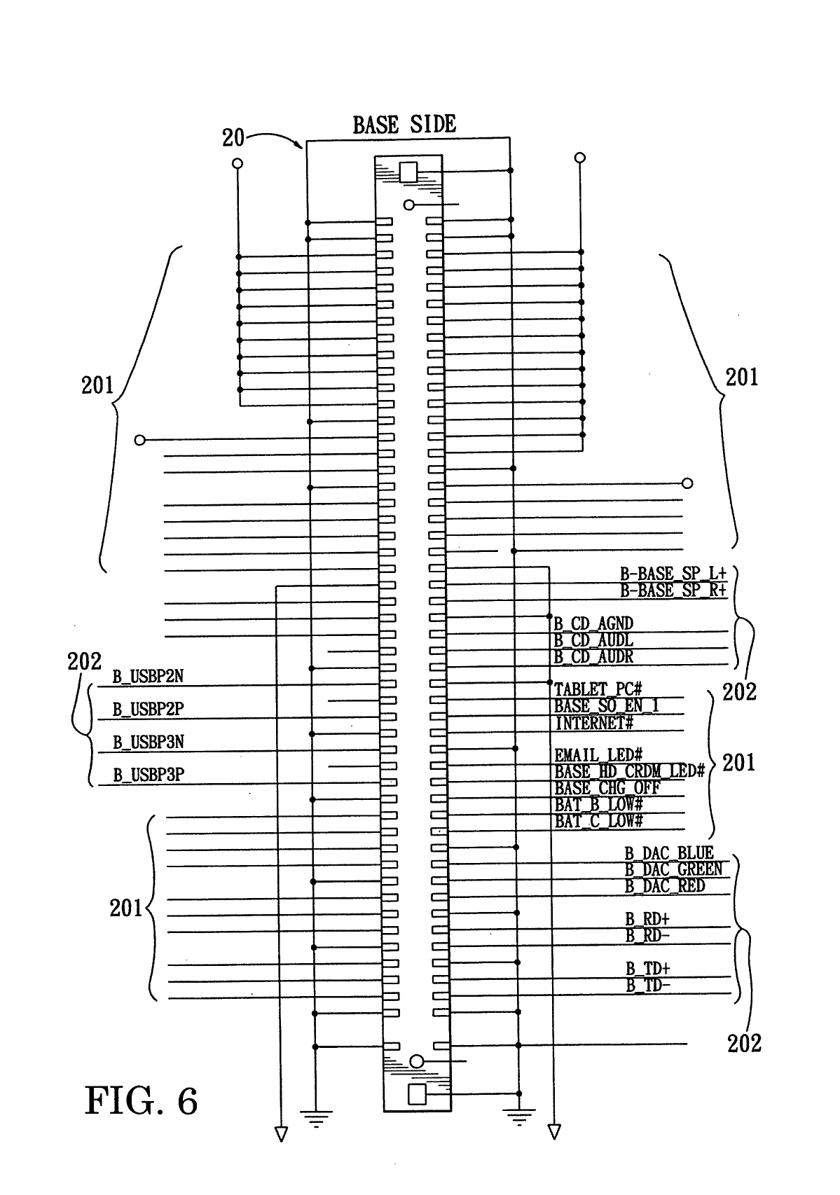

FIG. 6 illustrates the configuration of the FPC terminal set 201 and the FPC-end-terminal set 202 of each of the hybrid connectors 20, which is similar to that of the terminal set of a conventional FPC connector. The FPC terminal set 201 of one of the hybrid connectors 20 is electrically connected to the FPC terminal set 201 of the other of the hybrid connectors 20 through the FPC cable line 21. In this embodiment, the FPC-end-terminal set 202, which is electrically connected to the wire cable line 24, is used for transmitting signals such as USB 2.0 signals (including four signals that are labeled as USBP2N, USBP2P, USBP3N, and USBP3P in FIG. 6), LAN signals(including four signals that are labeled as RD+, RD−, TD+, and TD− in FIG. 6), Audio signals for Speakers (including two signals that are labeled as Base_SP_R+ and Base_SP_L+ in FIG. 6), Audio signals for CDROM(including three signals that are labeled as CD_AUDR, CD_AGND, and CD_AUDL in FIG. 6), and VGA signals for external monitor (including three signals that are labeled as DAC_Blue, DAC_Green, and DAC_Red in FIG. 6).

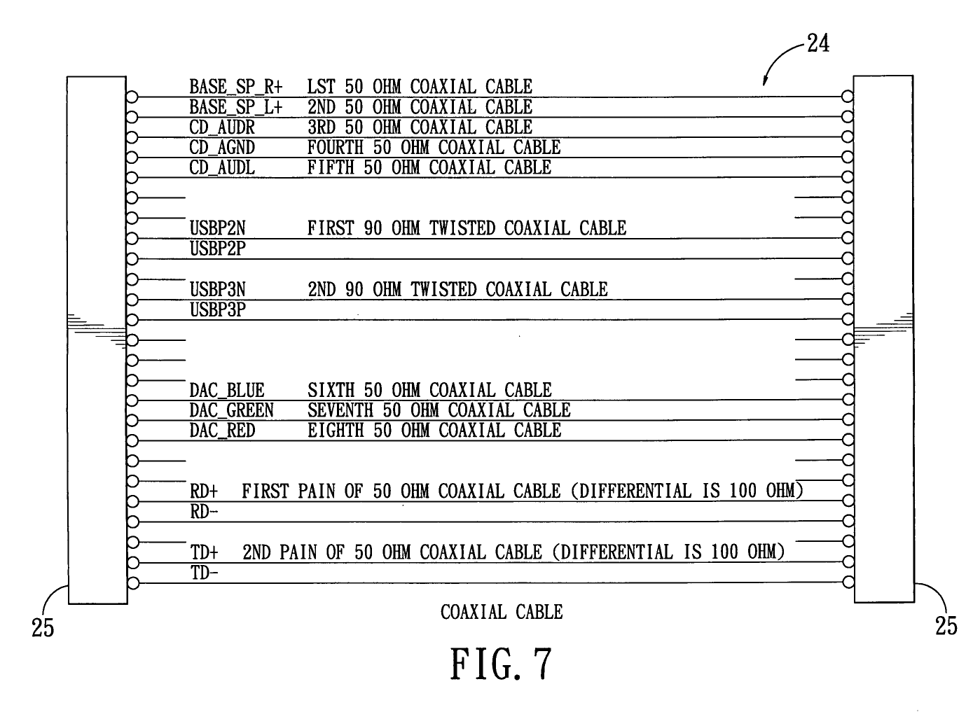

FIG. 7 illustrates the configuration of the wire cable line 24. The wire cable line 24, which is connected electrically to the FPC-end-terminal set 202 of the hybrid connectors 20, includes first and second 90 ohm twisted coaxial cables for transmitting the USB 2.0 signals, first and second 50 ohm coaxial cables for transmitting the Audio signals for Speakers, third, fourth, and fifth 50 ohm coaxial cables for transmitting the Audio signals for CDROM, sixth, seventh, and eighth 50 ohm coaxial cables for transmitting the VGA signals, and first and second pairs of 50 ohm coaxial cable for transmitting the LAN signals.

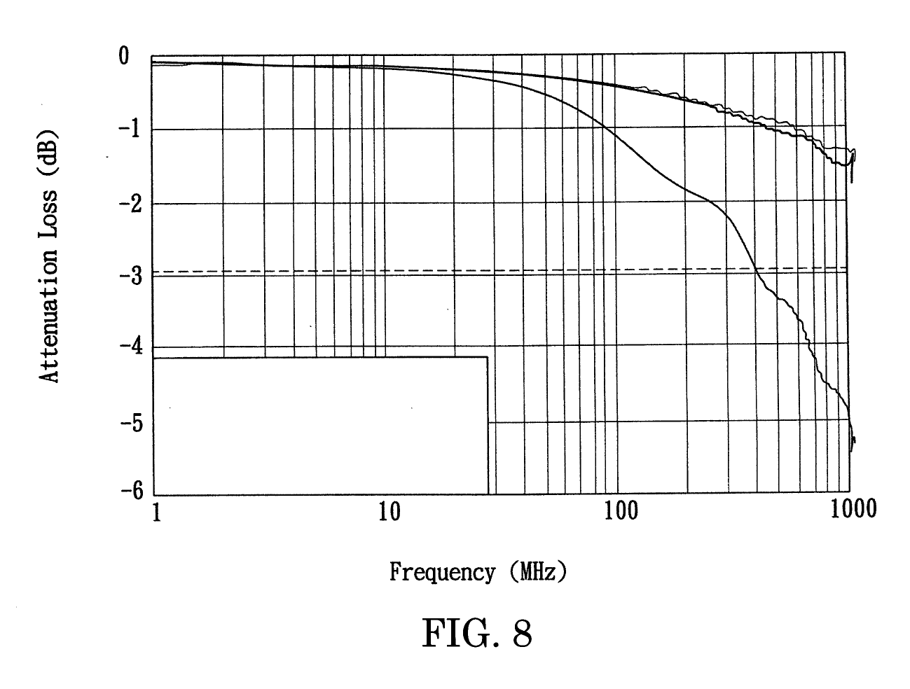

FIG. 8 illustrates an attenuation loss graph for a FPC cable, a coaxial cable, and a Twinax cable, each having a 250 mm length, for supporting USB 2.0 signals under various frequencies. For instance, the maximum allowable attenuation loss requirement for USB 2.0 signals running under 400 MHz is 5.8 db. The results shown in FIG. 8 show that when the 250 mm FPC cable is used to transmit the USB 2.0 signals, the attenuation loss reaches about 3 db, which will reach about 6 db, when the length is 500 mm long. However, when the 250 mm coaxial cable or Twinax cable is used to transmit the USB 2.0 signals, the attenuation loss reaches only about 1.4 db, which will reach about 2.8 db, when the length is 500 mm long.

With the inclusion of the wire cable 24 in the flexible hybrid cable 2 of this invention, the aforesaid drawback associated with the prior art can be eliminated.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

1-6. (canceled)

7. A flexible hybrid cable for transmitting high and low speed signals between first and second devices, comprising:
a pair of connectors adapted to be connected to the first and second devices, respectively;
a FPC cable extending between and connected directly to said connectors for establishing a low speed signal transmission path between the first and second devices; and
at least one pair of coaxial cables extending between and connected directly to said connectors for establishing a high speed signal transmission path so as to reduce attenuation loss of the high speed signals transmitted between the first and second devices.

8. The flexible hybrid cable of claim 7, wherein said coaxial cables are 90 Ohm twisted coaxial cables for transmitting USB 2.0 signals between the first and second devices.

9. The flexible hybrid cable of claim 1, wherein said coaxial cables are 50 Ohm coaxial cables for transmitting audio signals between the first and second devices.
